(19) United States
(12) Patent Application Publication
(10) Pub. No.: US 2007/0200108 A1
(43) Pub. Date: Aug. 30, 2007

(54) Storage node, phase change random access memory and methods of fabricating the same

(75) Inventors: Jin-Seo Noh, Seoul (KR); Ki-Joon Kim, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/654,004

(22) Filed: Jan. 17, 2007

(30) Foreign Application Priority Data
Feb. 27, 2006 (KR) 10-2006-0018886

(51) Int. Cl. H01L 47/00

(52) U.S. Cl. 257/4; 257/E29.17

(57) ABSTRACT

A storage node, a phase change random access memory having an improved structure to improve adhesion of a phase change material layer and methods of fabricating the same are provided. The storage node may include a bottom electrode, a top electrode, a phase change material layer inserted between the bottom electrode and the top electrode, and an adhesion interfacial layer inserted between the bottom electrode and the phase change material layer. The phase change random access memory may include a switching device and the storage node connected to the switching device.

### PRIORITY STATEMENT

This application claims priority under 35 U.S.C. § 119 to Korean Patent Application No. 10-2006-0018886, filed on Feb. 27, 2006, in the Korean Intellectual Property Office (KIPO), the entire contents of which are incorporated herein by reference.

### BACKGROUND

1. Field

Example embodiments relate to a storage node, a phase change random access memory and methods of fabricating the same. Other example embodiments relate to a storage node, a phase change random access memory device having an improved structure for improving adhesion of a phase change material layer and methods of fabricating the same.

2. Description of the Related Art

A phase change random access memory (PRAM) is a device that stores binary information using characteristics of a phase change material (e.g., GeSbTe) which allows a change from a crystalline state to an amorphous state by the local heat generated by an electric pulse. In the PRAM, a memory cell memorizing binary information may include a phase change layer, a heater and a switch transistor. The transistor may be formed on a silicon wafer, and the heater and the phase change layer may be formed on the transistor. The phase change layer may be composed of a GeSbTe (GST) material. The GST may be a kind of a material, which is used in an optical recording apparatus (e.g., DVD and/or CD-RW) and may be chalcogenide. A heater may be used to heat the phase change layer. The phase change layer may cause a phase change to a crystalline state or an amorphous state in accordance with a heated state, so that current or voltage is varied in accordance with resistance, thereby allowing the PRAM to store and read binary information. A DRAM as a volatile memory or a flash memory as a nonvolatile memory may store binary information as charge type (charge-base memory), but because a PRAM stores binary information as resistance type (resistance-base memory), the PRAM may be discriminated from other memories.

The PRAM may have binary information in circuits that may be discriminated because a signal ratio of a binary state (as one of the standards estimating a performance of memory device storing binary information) may be higher than that in other memory devices and a relatively high voltage may not be necessary for its operation. When the signal ratio of a binary state is indicated by a resistance ratio, it may be about 40 times or more than that in other memory devices, a wider dynamic range may be ensured, and the PRAM may not be influenced by the size of a memory node. The PRAM may have improved scalability even though a relatively high-integration technology of semiconductor circuits is continuously developed. The PRAM may have a write speed that is higher than that of a flash memory by about 10 times or more, because the phase change of the phase change layer may occur more quickly.

The fabrication of the conventional PRAM may not have improved adhesion between a GST thin film and a lower material layer there under. During a developing/lift-off process after the GST thin film is deposited, a peeling phenomenon, where the GST thin film of the phase change layer may be separated from the lower material layer, may occur. When the peeling phenomenon occurs, subsequent processes for fabricating the PRAM may be difficult to perform, and reliability and reproducibility may be deteriorated in the fabrication of the PRAM. The peeling phenomenon may deteriorate the switching characteristics of the PRAM, and may cause an initial resistance value during the switching operation of the PRAM to increase. A structure of the PRAM, improved to suppress the peeling phenomenon, may be required in the fabrication processes of the PRAM.

### SUMMARY

Example embodiments provide a storage node, a phase change memory having an improved structure to improve adhesion of a phase change material layer and methods of fabricating the same.

According to example embodiments, a storage node may include a bottom electrode, a top electrode, a phase change material layer inserted the bottom electrode and the top electrode, an adhesion interfacial layer between the bottom electrode and the phase change material layer. A phase change memory may include a switching device and the storage node according to example embodiments connected to the switching device.

The adhesion interfacial layer may be composed of Ge—N and/or Ge—O—N material and may be formed with a thickness of about 30 Å or less (e.g., in a range of about 10 Å to about 30 Å). The bottom electrode may include a bottom electrode contact thereon to reduce a contact area with the adhesion interfacial layer. The adhesion interfacial layer may be between the bottom electrode contact and the phase change material layer. The phase change material layer may be composed of a chalcogenide material (e.g., GeSbTe).

According to other example embodiments, a method of fabricating a storage node may include forming a bottom electrode, forming an adhesion interfacial layer on the bottom electrode, forming a phase change material layer on the adhesion interfacial layer and forming a top electrode on the phase change material layer. According to other example embodiments, a method of fabricating a phase change memory may include forming a switching device on a substrate and forming a storage node connected to the switching device.

The adhesion interfacial layer may be composed of Ge—N or Ge—O—N material, and may be formed with a thickness of about 30 Å or less (e.g., in a range of about 10 Å to about 30 Å). After forming the bottom electrode, the method may further include forming a bottom electrode contact on the bottom electrode. The phase change material layer may be composed of a chalcogenide material (e.g., GeSbTe).

The adhesion interfacial layer may be formed using a vapor deposition process. The vapor deposition process may include reactive sputtering, and the adhesion interfacial layer may be formed by sputtering a Ge target in a mixture gas ambient including Ar and N₂. A mixture ratio of Ar and N₂ may be in a range of about 5:1˜about 100:1. The mixture gas may further include oxygen. A sputtering power may be in a range of about 10 W to about 80 W and a deposition temperature of the adhesion interfacial layer may be in a range of about 150° C. to about 350° C.

According to example embodiments, adhesion between the phase change material layer and the lower material layer in the storage node of the PRAM may be improved, and a peeling phenomenon of the phase change material layer in the fabrication of the PRAM may be suppressed.

### BRIEF DESCRIPTION OF THE DRAWINGS

Example embodiments will be more clearly understood from the following detailed description taken in conjunction with the accompanying drawings. FIGS. 1-6E represent non-limiting, example embodiments as described herein.

FIG. 1 is a diagram illustrating a PRAM device according to example embodiments;

FIG. 2 is a graph illustrating a binary information storing operation in the PRAM of FIG. 1;

FIG. 3 illustrates test results of the adhesion of a GST thin film deposited on a GeN interfacial layer;

FIG. 4 illustrates measurement results of initial resistance values of a PRAM having a GST thin film deposited on a GeN interfacial layer;

FIGS. 5A and 5B illustrate measurement results of the switching characteristics of a PRAM according to example embodiments and a conventional PRAM respectively; and

FIGS. 6A through 6E are diagrams illustrating processing sequences of a method of fabricating a PRAM according to example embodiments.

### DETAILED DESCRIPTION OF EXAMPLE EMBODIMENTS

Hereinafter, a phase change random access memory (PRAM) and a method of fabricating the same according to example embodiments will be described more fully hereinafter with reference to the accompanying drawings, in which preferred embodiments are shown. In the drawings, the thicknesses of layers and regions are exaggerated for clarity.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a diagram illustrating a PRAM according to example embodiments.

Referring to FIG. 1, the PRAM, according to example embodiments, may include a switching device 20 and a storage node S connected to the switching device 20. A transistor, as an example of the switching device 20, may be formed on a substrate 10. The transistor may include a source 12 and a drain 14, which are doped with conductive impurities, for example, n-type impurities, a channel region 16 between the source 12 and the drain 14 and gate stack structures 18 and 19 formed on the channel region 16. The gate stack structure may include a gate insulating layer 18 and a gate electrode 19. A first interlayer insulating layer 22 may be stacked on the transistor, and a first contact hole h₁ exposing the drain 14 may be formed on the first interlayer insulating layer 22. A conductive plug 24 may be formed in the first contact hole h₁ and the conductive plug 24 may connect the drain 14 and the storage node S. The first interlayer insulating layer 22 may be composed of a dielectric material (e.g., SiOₓ and/or SiOₓN_{y}).

The storage node S may include a bottom electrode (BE) 30, a top electrode (TE) 40, a phase change material (PCM) layer 38 inserted between the bottom electrode 30 and the top electrode 40 and an adhesion interfacial layer 36 inserted between the bottom electrode 30 and the phase change material layer 38. The bottom electrode 30 may further include a bottom electrode contact (BEC) 30a thereon in order to reduce a contact area with the adhesion interfacial layer 36. A second interlayer insulating layer 32 may be stacked on the bottom electrode 30 and a second contact hole h₂ exposing a portion of the bottom electrode 30 may be formed in the second interlayer insulating layer 32. The second contact hole h₂ may be filled with a conductive material (e.g., TiN and/or TiAlN) so as to provide the BEC 30a. The second interlayer insulating layer 32 may be composed of a dielectric material (e.g., SiOₓ and/or SiOₓN_{y}).

The adhesion interfacial layer 36 may be composed of Ge—N and/or Ge—O—N material and may be disposed between the bottom electrode 30 and/or the bottom electrode contact 30a and the phase change material layer 38 and may function to improve adhesion of the phase change material layer 38. The adhesion interfacial layer 36 may be formed with a thickness of 30 Å or less (e.g., in a range of about 10 Å to about 30 Å). According to example embodiments, because the adhesion interfacial layer 36 is provided in the storage node S, improved adhesion may be maintained between the phase change material layer 38 and material layers there underneath between the phase change material layer 38 and the bottom electrode contact 30a and between the phase change material layer 38 and the second interlayer insulating layer 32. A peeling phenomenon of the phase change material layer 38 may be suppressed in the fabrication processes of the PRAM, and thus, reliability and reproducibility of the fabrication of the PRAM may be improved. An initial resistance value during a switching operation of the PRAM may be reduced to one-half of that of the conventional PRAM and switching characteristics of the PRAM may be improved further than that of the conventional PRAM.

The phase change material layer 38 may be composed of a chalcogenide material (e.g., GeSbTe (GST)). For example, the phase change material layer 38 may include chalcogenide alloys (e.g., germanium-antimony-tellurium (Ge—Sb—Te), nitrogen-germanium-antimony-tellurium (N—Ge—Sb—Te), arsenic-antimony-tellurium (As—Sb—Te), indium-antimony-tellurium (In—Sb—Te), germanium-bismuth-tellurium (Ge—Bi—Te), tin-antimony-tellurium (Sn—Sb—Te), silver-arsenic-antimony-tellurium (Ag—In—Sb—Te), gold-arsenic-antimony-tellurium (Au—In—Sb—Te), germanium-arsenic-antimony-tellurium (Ge—In—Sb—Te), selenium-antimony-tellurium (Se—Sb—Te), tin-arsenic-antimony-tellurium (Sn—In—Sb—Te), arsenic-germanium-antimony-tellurium (As—Ge—Sb—Te) and/or any other suitable chalcogenide alloys). As another example, the phase change material layer 38 may include group VA elements-antimony-tellurium compounds (e.g., tantalum-antimony-tellurium (Ta—Sb—Te), niobium-antimony-tellurium (Nb—Sb—Te), vanadium-antimony-tellurium (V—Sb—Te) and/or any other suitable compound) and/or may include group VA elements-antimony-selenium compounds (e.g., tantalum-antimony-selenium (Ta—Sb—Se), niobium-antimony-selenium (Nb—Sb—Se), vanadium-antimony-selenium (V—Sb—Se) and/or any other suitable compound). As further another example, the phase change material layer 38 may include group VIA elements-antimony-tellurium compounds (e.g., tungsten-antimony-tellurium (W—Sb—Te), molybdenum-antimony-tellurium (Mo—Sb—Te), chrome-antimony-tellurium (Cr—Sb—Te) and/or any other suitable compound) and/or may include group VIA elements-antimony-selenium compounds (e.g., tungsten-antimony-selenium (W—Sb—Se), molybdenum-antimony-selenium (Mo—Sb—Se), chrome-antimony-selenium (Cr—Sb—Se) and/or any other suitable compound).

The phase change material layer 38 may be composed of ternary phase change chalcogenide alloys, but the phase change material layer 38 may also be composed of binary phase-change chalcogenide alloys and/or quaternary phase-change chalcogenide alloys. For example, the binary phase-change chalcogenide alloys may be one of a Ga—Sb, Ge—Sb, In—Sb, In—Se, Sb₂—Te₃ and/or Ge—Te alloy. The quaternary phase-change chalcogenide alloys may be a Ag—In—Sb—Te, (Ge—Sn)—Sb—Te, Ge—Sb—(Se—Te) and/or Te₈₁—Ge₁₅—Sb₂—S₂ alloy. In example embodiments as described above, the material of the phase change material layer 38 may be replaced with a transition metal oxide having a plurality of resistance states. For example, the phase change material layer 38 may be composed of at least one material selected from the group including NiO, TiO₂, HfO, Nb₂O₅, ZnO, WO₃, CoO and PCMO(PrₓCa₍₁₋ₓ₎MnO₃).

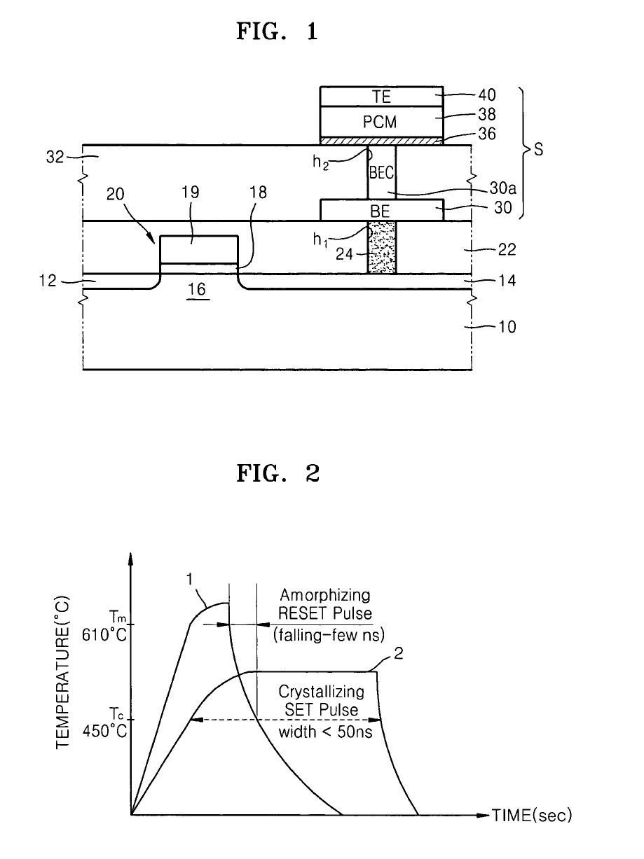

FIG. 2 is a graph illustrating a binary information storing operation in the PRAM of FIG. 1. Referring to FIG. 2, a method of storing and removing data in and from the storage node of the PRAM may be explained. In the graph, a transverse axis represents time (t) and a vertical axis represents temperature (° C.) in the phase change material layer 38. In the process of writing binary information by applying a pulse type of current to the PRAM, the pulse type of current may be divided to set pulse and reset pulse depending on its purpose. The set pulse may be applied to change the structure of the phase change material layer 38, for example, a GST thin film to a crystalline state, and may have a width of about 50 ns or less. The set pulse type of current having an intensity required to generate the heat of the crystallization temperature of the material or higher may be applied. The reset pulse may be applied to change the structure of the GST thin film to an amorphous state, and the reset pulse type of current having an intensity required to generate heat at the melting temperature of the material or higher may be applied. In the graph, after heating the phase change material layer 38 to a temperature higher than the melting temperature Tₘ for a short time T₁ and quenching it relatively quickly, the phase change material layer 38 may be changed to an amorphous state (first curve). After heating the phase change material layer 38 at a temperature lower than the melting temperature Tₘ and higher than the crystallization temperature T_{c} for a time T₂ longer than T₁ and quenching it relatively slowly, the phase change material layer 38 may be changed to a crystalline state (second curve). A specific resistance of the phase change material layer 38 having an amorphous state may be higher than that of the phase change material layer 38 having a crystalline state. It may be determined whether the information stored in the PRAM storage node is logic ‘1’ or ‘0’ by detecting the current flowing through the phase change material layer 38 in a writing mode.

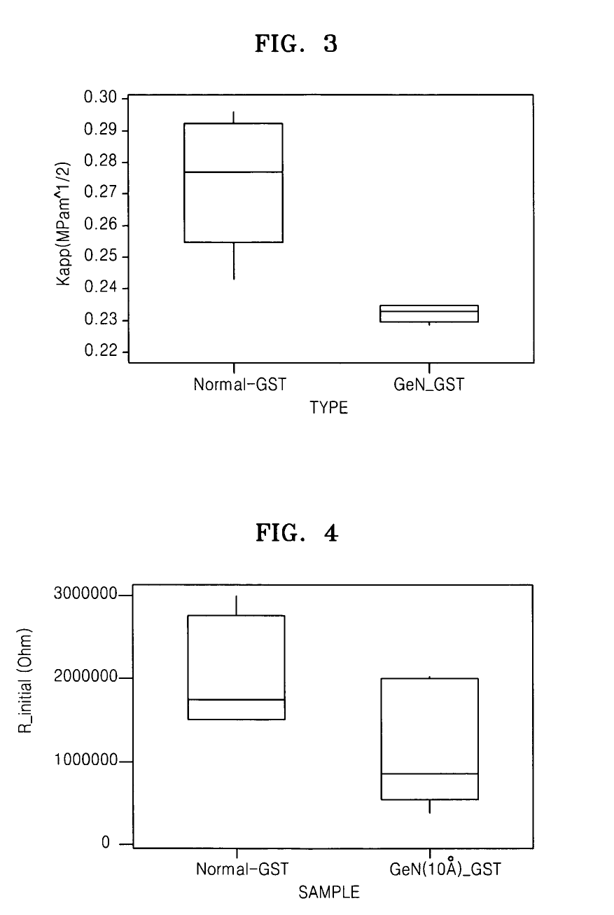

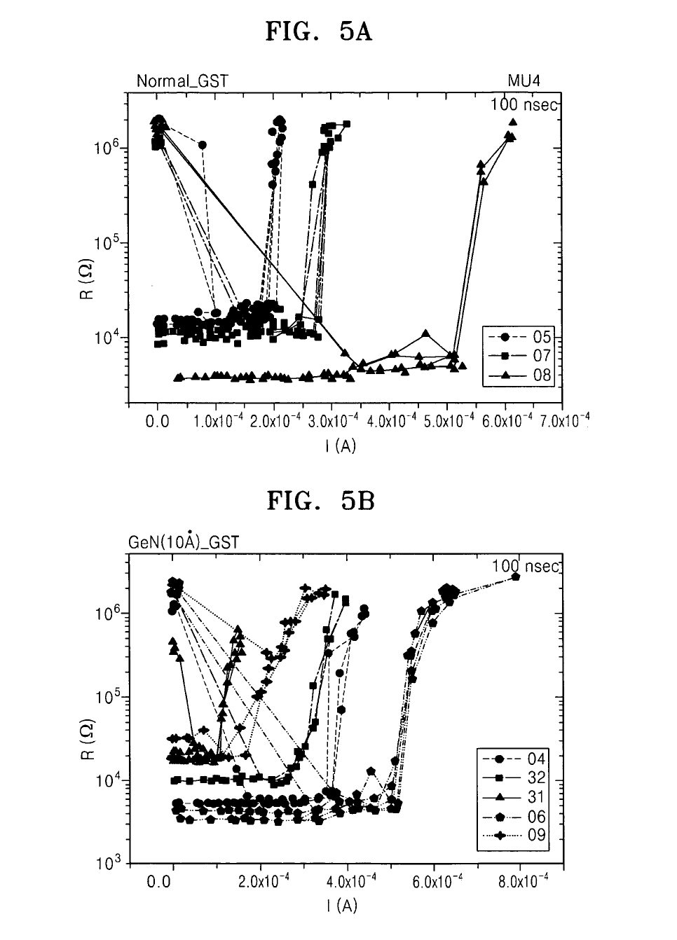

FIG. 3 illustrates test results of the adhesion of a GST thin film deposited on a GeN interfacial layer (GeN_GST), and FIG. 4 illustrates measurement results of initial resistance values of a PRAM having a GST thin film deposited on a GeN interfacial layer. FIGS. 5A and 5B illustrate measurement results of the switching characteristics of a PRAM (GeN_GST) according to example embodiments and the conventional PRAM (normal GST) respectively.

Referring to FIG. 3, a vertical axis (Kapp) of the graph represents an applied fracture intensity, and a unit is MPa·square root(m). The applied fracture intensity may be interpreted as an effective energy to break the bonding by an applied stress. The test result of the adhesion of the conventional GST thin film (normal GST) without the GeN interfacial layer is also compared. As illustrated in FIG. 3, the adhesion of the GeN_GST thin film may be improved by about 20% to the adhesion of the normal GST. Referring to FIG. 4, a vertical axis of the graph represents an initial resistance value (R_{—initial}) of a PRAM, and its unit is ohm (Ω). The measurement result of the initial resistance value of the conventional GST thin film (normal_GST) without a GeN interfacial layer may also be compared. Comparing the results in FIGS. 4, 5A and 5B, it may be acknowledged that an initial resistance value in the PRAM (GeN_GST) according to example embodiments is decreased to one-half that of the conventional PRAM and the switching characteristics may be improved.

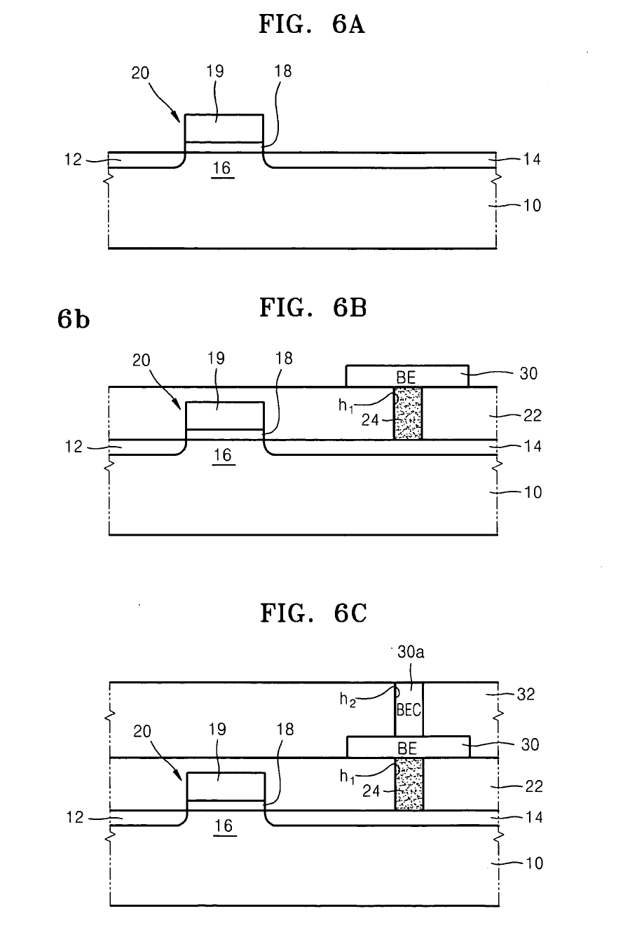

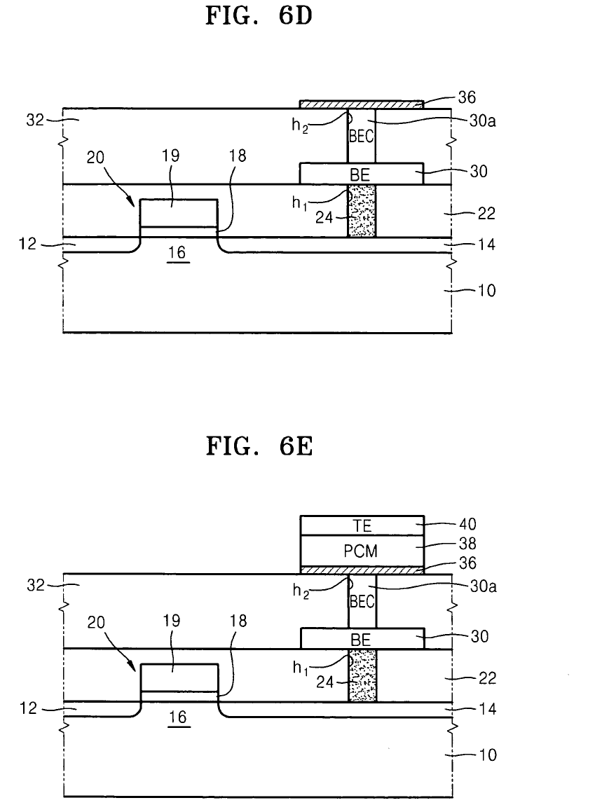

FIGS. 6A-6E are diagrams illustrating processing sequences of a method of fabricating a PRAM according to example embodiments. In example embodiments, each material layer may be formed using a vapor deposition method which is normally used in the fabrication of semiconductor memory devices, for example, a reactive sputtering method as physical vapor deposition (PVD) and chemical vapor deposition (CVD), a metal organic chemical vapor deposition (MOCVD) method and/or an evaporation method.

Referring to FIG. 6A, a switching device 20, for example, a transistor, may be formed on a substrate 10. A source 12 and a drain 14 may be formed by doping the silicon wafer substrate 10 with conductive impurities and a channel region 16 may be formed between them. A gate insulating layer 18 and a gate electrode 19 may be stacked on the channel region 16 so as to form a transistor. As a material of the transistor and a method of forming the same may be widely known, detailed description thereon will be omitted.

Referring to FIG. 6B, a first interlayer insulating layer 22 may be formed on the transistor 20 to bury the transistor 20, and the first interlayer insulating layer 22 may be composed of a dielectric material, for example, SiOₓ and/or SiOₓN_{y}. A first contact hole h₁, exposing the source 12 and/or the drain 14, may be formed in the first interlayer insulating layer 22. The first contact hole h₁ may be filled with a conductive material so as to form a conductive plug 24. A bottom electrode 30 may be formed to contact the conductive plug 24. In the PRAM, because a material of the bottom electrode 30 and a method of forming the same may be widely known, detailed description thereon will be omitted.

Referring to FIG. 6C, a second interlayer insulating layer 32 may be formed on the first interlayer insulating layer 22 to bury the bottom electrode 3.0, and the second interlayer insulating layer 32 may be composed of a dielectric material, for example, SiOₓ and/or SiOₓN_{y}. A second contact hole h₂, exposing a portion of the bottom electrode 30, may be formed in the second interlayer insulating layer 32. A resistive heater, for example, a bottom electrode contact 30a, may be formed in the second contact hole h₂, and the resistive heater may be composed of a TiN and/or TiAlN material. Because an upper surface of the bottom electrode contact 30a is smaller in width than that of the bottom electrode 30, a smaller contact area may be provided at the upper surface of the bottom electrode contact 30a.

Referring to FIG. 6D, an adhesion interfacial layer 36, covering the upper surface of the bottom electrode contact 30a, may be formed on the second interlayer insulating layer 32. The adhesion interfacial layer 36 may be composed of a Ge—N and/or Ge—O—N material, and may have improved adhesion with the second interlayer insulating layer 32 and/or the bottom electrode contact 30a. The adhesion interfacial layer 36 may be formed with a thickness of about 30 Å or less (e.g., in a range of about 10 Å to about 30 Å). The adhesion interfacial layer 36 may be formed using a vapor deposition method, and the vapor deposition method may employ various methods (e.g., reactive sputtering, MOCVD, evaporation and/or any other suitable method). For example, the adhesion interfacial layer 36 may be formed by sputtering a Ge target using an ambient mixture gas including Ar and N₂. A mixture ratio of Ar and N₂ may be controlled to a range of about 5:1˜about 100:1 (e.g., a range of about 5:1˜about 25:1). Power of the sputtering may be controlled to a range of about 10 W to about 80 W (e.g., about 40 W). An appropriate power value may be determined depending on a size of the target. A deposition temperature of the adhesion interfacial layer 36 may be in a range of about 150° C. to about 350° C. (e.g., about 200° C.). The process parameters may be achieved from experiment results, and the adhesion interfacial layer 36 may be formed with an improved layer property in the ranges of the parameters exemplified as above. The mixture gas may further include oxygen, and thus, the adhesion interfacial layer 36 may be composed of a Ge—O—N material in the mixture ambient gas further including oxygen. A following Table 1 shows measurement results of a sheet resistance of the adhesion interfacial layer 36 in accordance with each process parameter (experiment with three conditions). The unit of the sheet resistance is k Ω/sq.

TABLE 1

| | VARIATION 1 | VARIATION 2 | |
|---|---|---|---|
| | (200° C., | (200° C., | VARIATION 3 |
| | Ar 50 sccm, | Ar 50 sccm, | (200° C., Ar 50 sccm, |
| | N₂ 2 sccm) | N₂ 5 sccm) | N₂ 10 sccm) |
| SHEET | 1753.14 | 11197.57 | 50154.28 |
| RESISTANCE | | | |
| (kΩ/sq) | | | |

Referring to FIG. 6E, a phase change material layer 38 and a top electrode 40 may be sequentially formed on the adhesion interfacial layer 36. The phase change material layer 38 may be composed of a chalcogenide material, for example, GeSbTe (GST). For example, the phase change material layer 38 may include chalcogenide alloys (e.g., germanium-antimony-tellurium (Ge—Sb—Te), nitrogen-germanium-antimony-tellurium (N—Ge—Sb—Te), arsenic-antimony-tellurium (As—Sb—Te), indium-antimony-tellurium (In—Sb—Te), germanium-bismuth-tellurium (Ge—Bi—Te), tin-antimony-tellurium (Sn—Sb—Te), silver-arsenic-antimony-tellurium (Ag—In—Sb—Te), gold-arsenic-antimony-tellurium (Au—In—Sb—Te), germanium-arsenic-antimony-tellurium (Ge—In—Sb—Te), selenium-antimony-tellurium (Se—Sb—Te), tin-arsenic-antimony-tellurium (Sn—In—Sb—Te), arsenic-germanium-antimony-tellurium (As—Ge—Sb—Te) and/or any other suitable chalcogenide alloys). As another example, the phase change material layer 38 may include group VA elements-antimony-tellurium compounds (e.g., tantalum-antimony-tellurium (Ta—Sb—Te), niobium-antimony-tellurium (Nb—Sb—Te), vanadium-antimony-tellurium (V—Sb—Te) and/or any other suitable compound) and/or may include group VA elements-antimony-selenium compounds (e.g., tantalum-antimony-selenium (Ta—Sb—Se), niobium-antimony-selenium (Nb—Sb—Se), vanadium-antimony-selenium (V—Sb—Se) and/or any other suitable compound). As another example, the phase change material layer 38 may include group VIA elements-antimony-tellurium compounds (e.g., tungsten-antimony-tellurium (W—Sb—Te), molybdenum-antimony-tellurium (Mo—Sb—Te) and/or chrome-antimony-tellurium (Cr—Sb—Te)) and/or may include group VIA elements-antimony-selenium compounds (e.g., tungsten-antimony-selenium (W—Sb—Se), molybdenum-antimony-selenium (Mo—Sb—Se) and/or chrome-antimony-selenium (Cr—Sb—Se)).

The phase change material layer 38 may be composed of ternary phase change chalcogenide alloys, but the phase change material layer 38 may also be composed of binary phase-change chalcogenide alloys and/or quaternary phase-change chalcogenide alloys. For example, the binary phase-change chalcogenide alloys may be one of a Ga—Sb, Ge—Sb, In—Sb, In—Se, Sb₂—Te₃ and/or Ge—Te alloy. The quaternary phase-change chalcogenide alloys may be Ag—In—Sb—Te, (Ge—Sn)—Sb—Te, Ge—Sb—(Se—Te) and/or Te₈₁—Ge₁₅—Sb₂—S₂ alloy. In example embodiments as described above, the material of the phase change material layer 38 may be replaced with a transition metal oxide having a plurality of resistance states. For example, the phase change material layer 38 may be composed of at least one material selected from the group including NiO, TiO₂, HfO, Nb₂O₅, ZnO, WO₃, CoO and PCMO(PrₓCa₍₁₋ₓ₎MnO₃). In the PRAM, as a material of the top electrode 40 and a method of forming the same are widely known, detailed description thereon will be omitted. Through the processes as above, the PRAM may be provided with improved adhesion between the phase change material layer and the lower material layer in the storage node S.

According to example embodiments, adhesion between the phase change material layer and the lower material layer in the storage node of the PRAM may be improved by about 20% compared with the conventional PRAM, and a peeling phenomenon of the phase change material layer may be suppressed in the fabrication processes of the PRAM. Reliability and reproducibility of the fabrication of the PRAM may be improved. An initial resistance value during a switching operation of the PRAM may be reduced to one-half that of the conventional PRAM and switching characteristics of the PRAM may be improved further than that of the conventional PRAM.

While example embodiments have been particularly shown and described with reference to example embodiments thereof with accompanying drawings, it will be understood by those of ordinary skill in the art that the embodiments are just exemplified, and various changes in form and details may be made therein without departing from the spirit and scope of the following claims. Therefore, example embodiments are not limited to the structures and the processing sequences illustrated and explained in the embodiments, and must be protected based on the technical spirit of the following claims.

What is claimed is:

1. A storage node comprising:
a bottom electrode;
a top electrode;
a phase change material layer between the bottom electrode and the top electrode; and
an adhesion interfacial layer between the bottom electrode and the phase change material layer.

2. A phase change memory comprising:
a switching device; and
the storage node of claim 1 connected to the switching device.

3. The storage node of claim 1, wherein the adhesion interfacial layer is composed of Ge—N or Ge—O—N material.

4. The storage node of claim 1, wherein the adhesion interfacial layer is formed with a thickness of about 30 Å or less.

5. The storage node of claim 1, wherein the bottom electrode includes a bottom electrode contact thereon to reduce a contact area with the adhesion interfacial layer.

6. The storage node of claim 5, wherein the adhesion interfacial layer is between the bottom electrode contact and the phase change material layer.

7. The storage node of claim 1, wherein the phase change material layer is composed of a chalcogenide material.

8. The storage node of claim 7, wherein the chalcogenide material is a GeSbTe material.

9. A method of fabricating a storage node comprising:
forming a bottom electrode;
forming an adhesion interfacial layer on the bottom electrode;
forming a phase change material layer on the adhesion interfacial layer; and
forming a top electrode on the phase change material layer.

10. A method of fabricating a phase change memory comprising:
forming a switching device on a substrate; and
forming the storage node according to claim 9 connected to the switching device.

11. The method of claim 9, wherein forming the adhesion interfacial layer includes forming a Ge—N or Ge—O—N material.

12. The method of claim 9, wherein forming the adhesion interfacial layer includes forming the adhesion interfacial layer with a thickness of about 30 Å or less.

13. The method of claim 12, wherein forming the adhesion interfacial layer includes using a vapor deposition process.

14. The method of claim 13, wherein the vapor deposition process includes reactive sputtering.

15. The method of claim 9, wherein forming the adhesion interfacial layer includes sputtering a Ge target in a mixture gas ambient including Ar and N₂.

16. The method of claim 15, wherein a mixture ratio of Ar and N₂ is in a range of about 5:1˜about 100:1.

17. The method of claim 15, wherein the mixture gas further includes oxygen.

18. The method of claim 15, wherein a sputtering power is in a range of about 10 W to about 80 W.

19. The method of claim 15, wherein a deposition temperature of the adhesion interfacial layer is in a range of about 150° C. to about 350° C.

20. The method of claim 9, after forming the bottom electrode, the method further comprising:
forming a bottom electrode contact on the bottom electrode.

21. The method of claim 9, wherein forming the phase change material layer includes forming a chalcogenide material.

22. The method of claim 21, wherein the chalcogenide material is a GeSbTe material.
